(19) United States
(12) Patent Application Publication
(10) Pub. No.: US 2021/0232792 A1
(43) Pub. Date: Jul. 29, 2021

(54) DISPLAY PANEL, MANUFACTURING METHOD THEREOF AND DISPLAY APPARATUS

(71) Applicants: CHENGDU BOE OPTOELECTRONICS TECHNOLOGY CO., LTD, Chengdu, Sichuan (CN); BOE TECHNOLOGY GROUP CO., LTD., Beijing (CN)

(72) Inventors: Guangjie Yang, Beijing (CN); Wenfeng Guo, Beijing (CN); Li Wang, Beijing (CN); Fei Li, Beijing (CN)

(73) Assignees: CHENGDU BOE OPTOELECTRONICS TECHNOLOGY CO., LTD, Chengdu, Sichuan (CN); BOE TECHNOLOGY GROUP CO., LTD., Beijing (CN)

(21) Appl. No.: 16/954,368

(22) PCT Filed: Feb. 21, 2020
(86) PCT No.: PCT/CN2020/076137

§ 371 Date: Jun. 16, 2020

(30) Foreign Application Priority Data
Mar. 5, 2019 (CN) 201910163867.1

(51) Int. Cl. G06K 9/00; H01L 27/32; H01L 51/56

(52) U.S. Cl. CPC G06K 9/0004; H01L 27/3234; H01L 27/14678; H01L 51/56; H01L 27/3272

(57) ABSTRACT

The embodiments of the present disclosure relate to a display panel. The display panel may include an array substrate having a display surface and a back surface opposite the display surface; a fingerprint recognition device on a side of the back surface of the array substrate; and a connection portion between the array substrate and the fingerprint recognition device. The connection portion may have a first surface and a second surface opposite the first surface. A surface of the fingerprint recognition device facing the back surface of the array substrate may be a convex-concave surface comprising a concave surface and a convex surface, and there is a gap between the convex surface and the back surface.

### CROSS-REFERENCE TO RELATED APPLICATIONS

This application claims benefit of the filing date of Chinese Patent Application No. 201910163867.1 filed on Mar. 5, 2019, the disclosure of which is hereby incorporated in its entirety by reference.

### TECHNICAL FIELD

The disclosure relates to the field of display technology, in particular, to a display panel, a manufacturing method thereof and a display apparatus

### BACKGROUND

At present, the fingerprint recognition device is usually attached to a back surface of an array substrate by a connection portion. However, the thermal expansion coefficient and the contraction coefficient of the array substrate, the connection portion, and the fingerprint recognition device are different. In the reliability test, the array substrate, the connection portion and the fingerprint recognition device have different amount of deformation, so that the connections between the connection portion and the array substrate and between the connection portion and the fingerprint recognition device are prone to wrinkles, indentations, etc., which may be clearly seen from the display surface of the array substrate, thereby reducing product quality.

In order to solve the above problem, the commonly used solution is to increase the thickness of the connection portion. But this will increase the gap distance between the fingerprint recognition device and the array substrate, thereby affecting the fingerprint imaging effect and reducing fingerprint recognition sensitivity.

### BRIEF SUMMARY

An embodiment of the present disclosure provides a display panel. The display panel may include an array substrate having a display surface and a back surface opposite the display surface; a fingerprint recognition device on a side of the back surface of the array substrate; and a connection portion between the array substrate and the fingerprint recognition device. The connection portion may have a first surface and a second surface opposite the first surface. A surface of the fingerprint recognition device facing the back surface of the array substrate may be a convex-concave surface comprising a concave surface and a convex surface, and there is a gap between the convex surface and the back surface.

Optionally, the fingerprint recognition device comprises a mounting substrate; and a fingerprint recognition unit, wherein a surface of the mounting substrate facing the back surface of the array substrate comprises a fingerprint recognition area and a non-recognition area, the non-recognition area is the concave surface of the concave-convex surface, the fingerprint recognition unit is on the fingerprint recognition area, and a surface of the fingerprint recognition unit facing the back surface of the array substrate is the convex surface of the concave-convex surface.

Optionally, the array substrate comprises a light shielding layer, the light shielding layer comprises a small aperture imaging area, and an orthographic projection of the small aperture imaging area on the mounting substrate overlaps an orthographic project of the convex surface of the fingerprint recognition device on the mounting substrate.

Optionally, the small aperture imaging area comprises a plurality of openings in an array.

Optionally, the first surface of the connection portion connects the concave surface of the concave-convex surface of the fingerprint recognition device, and the second surface of the connection portion connects the back surface of the array substrate.

Optionally, a gap distance of the gap between the convex surface and the back surface is less than or equal to about 50 μm.

Optionally, an orthographic projection of the concave surface on the first surface is within the first surface.

Optionally, a shortest distance between the first surface and the second surface of the connection portion is greater than a shortest distance from the convex surface to the concave surface of the concave-convex surface.

Optionally, the connection portion is an annular structure, and the connection portion surrounds the convex surface.

Optionally, the connection portion comprises a frame sealant.

Optionally, a corner formed by the fingerprint recognition device and the first surface is sealed with an edge sealant.

Optionally, the array substrate is an organic light emitting array substrate.

Optionally, the organic light emitting array substrate comprises an organic light emitting layer, and the light shielding layer is between the organic light emitting layer and the fingerprint recognition device.

Optionally, the organic light emitting layer comprises a plurality of light-emitting devices at intervals, and an orthographic projection of the small aperture imaging area on the organic light emitting layer is at the intervals among the light-emitting devices.

Optionally, the mounting substrate comprises a driving circuit board configured to drive the fingerprint recognition unit.

One embodiment of the present disclosure provides a method for manufacturing a display panel, comprising providing an array substrate having a display surface and a back surface opposite the display surface; providing a fingerprint recognition device; and connecting the array substrate and the fingerprint recognition device through a connection portion having a first surface and a second surface opposite the first surface. A surface of the fingerprint recognition device facing the back surface may be a convex-concave surface comprising a concave surface and a convex surface, and there is a gap between the convex surface and the back surface.

Optionally, the first surface of the connection portion is configured to be connected to the concave surface of the concave-convex surface of the fingerprint recognition device, and the second surface of the connection portion is configured to be connected to the back surface of the array substrate.

Optionally, a shortest distance between the first surface and the second surface of the connection portion is greater than a shortest distance from the convex surface to the concave surface of the concave-convex surface, thereby forming the gap between the convex surface and the back surface.

One embodiment of the present disclosure is a display apparatus comprising the display panel according to one embodiment of the present disclosure.

### BRIEF DESCRIPTION OF THE DRAWINGS

The drawings are used to provide a further understanding of the technical solutions of the present disclosure, and constitute a part of the specification, which together with the embodiments of the present disclosure are used to explain the technical solutions of the present disclosure, and do not constitute a limitation of the technical solutions of the present disclosure. Obviously, the drawings in the following description are only some embodiments of the present disclosure, and those skilled in the art can obtain other drawings according to these drawings without any creative work.

FIG. 1 is a schematic structural diagram of a display panel in the related art;

FIG. 2A is a schematic structural diagram of a display panel according to one embodiment of the present disclosure;

FIG. 2B is a schematic top view of a display panel according to one embodiment of the present disclosure;

FIG. 2C is a schematic top view of a projection relationship between a small aperture imaging area of the light shielding layer and convex surface of the fingerprint recognition device on the mounting substrate according to one embodiment of the present disclosure.

FIG. 3 is a schematic structural diagram of a fingerprint recognition device according to one embodiment of the present disclosure; and

FIG. 4 is a flowchart of a method for manufacturing a display panel according to one embodiment of the present disclosure.

### DETAILED DESCRIPTION

The specific embodiments of display panel, manufacturing method thereof and display apparatus provided by the embodiments of the present disclosure are described in details below with reference to the accompanying drawings. It is understandable that the preferred embodiments described herein are intended to illustrate and explain the disclosure and are not intended to limit disclosure. The same reference numerals in the drawings denote the same or similar structures, and thus their detailed description will be omitted.

Although relative terms such as “above” and “below” are used in the specification to describe the relative relationship of one component to another component, these terms are used in this specification for convenience only, for example, in the accompanying drawings such that the direction of the example described. It is understandable that if the device of the icon is flipped upside down, the component described “above” will become the component “below”. When a structure is “on” another structure, it may mean that a structure is integrally formed on another structure, or that a structure is “directly” disposed on another structure, or that a structure is “indirectly” disposed through another structure on other structures.

The terms “a,” “an,” “the,” and “said” are used to mean presence of one or more elements/components, etc.; the terms “including” and “having” are used to mean the inclusiveness, meaning that there may be additional elements/components/etc. in addition to the listed elements/components/etc. In addition, the terms “first” and “second” are for illustration purposes only and are not to be construed as indicating or implying relative importance or implied reference to the quantity of indicated technical features. Thus, features defined by the terms “first” and “second” may explicitly or implicitly include one or more of the features. A number modified by “about” herein means that the number can vary by 10% thereof.

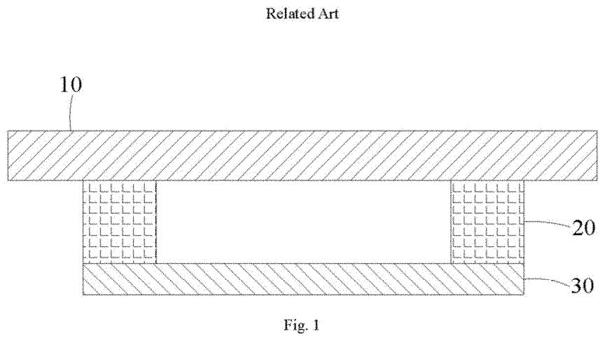

At present, the fingerprint recognition device 30 is mainly attached to the back surface of the array substrate 10 by using the connection portion 20, as shown in FIG. 1. However, the thermal expansion coefficient and the contraction coefficient of the array substrate 10, the connection portion 20, and the fingerprint recognition device 30 are different. Therefore in the reliability test, the amount of deformation of the array substrate 10, the connection portion 20, and the fingerprint recognition device is also different. In general, in the reliability test, the deformation amount of the array substrate 10 and the fingerprint recognition device 30 is small, and the deformation amount of the connection portion 20 is large, so that the connection portion connected to the array substrate 10 and the fingerprint recognition device 30 is prone to wrinkles, indentations. The wrinkles and indentations can be clearly seen from the display surface of the array substrate 10, thereby reducing the product quality.

In the related art, in order to reduce wrinkles, indentations at the joints between the connection portion 20 and the array substrate 10 and between the connection portion 20 and the fingerprint recognition device 30, it is often adopted to increase the thickness of the connection portion 20. Because the thickness of the connection portion 20 is increased, the strain of the connection portion 20 is reduced, so that the amount of deformation of the connection portion 20 can be reduced. As such, the problems of the wrinkles, indentations at the joints of the connecting portion 20 with the array substrate 10 and the fingerprint recognition device 30 respectively can be improved. As shown in the table below, taking the frame sealant as the connection portion as example, wherein the thickness of the sealant is 50 um or 100 um, and the order of indentation from light to heavy is indicated by L0, L1, L2, L3, L4.

| | #1 | #2 | #3 | #4 | #5 | #6 | #7 | #8 | #9 | #10 |
|---|---|---|---|---|---|---|---|---|---|---|
| 50 um | L3 | L2 | L3 | L3 | L2 | L2 | L3 | L2 | L3 | L3 |
| 100 um | L1 | L1 | L1 | L1 | L1 | L1 | L1 | L1 | L1 | L1 |

It can be seen from the data in the above table that after the thickness of frame sealant is increased from 50 um to 100 um, the indentation is reduced by 1˜2 grades, so that improvement effect is obvious.

However, since the current fingerprint recognition device 30 is generally a flat plate structure, if the thickness of the connection portion 20 is increased, the gap between the fingerprint recognition device 30 and the array substrate 10 is increased, thereby affecting the fingerprint imaging effect and decreasing fingerprint recognition sensitivity.

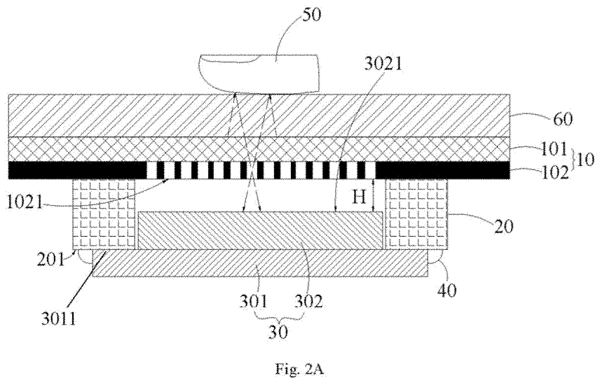

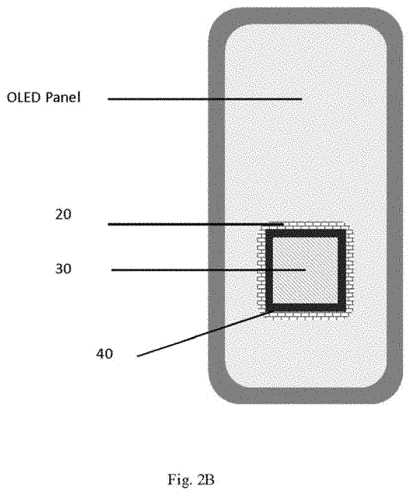

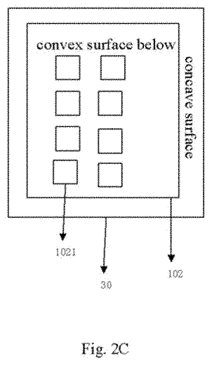

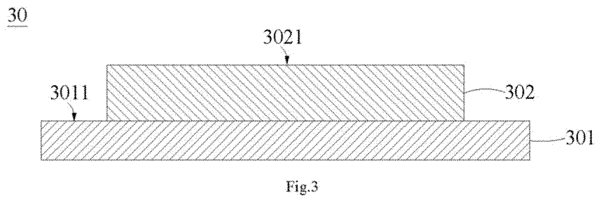

In order to solve the above technical problem, in one embodiment of the present disclosure, a display panel, applicable to a display apparatus such as a mobile phone or a tablet computer, is shown in FIGS. 2A and 3. The display panel may include an array substrate 10, a fingerprint recognition device 30, and a connection portion 20, wherein the array substrate 10 is used to display an image. In one embodiment, the array substrate 10 can perform image display on the side thereof opposite from the fingerprint recognition device 30, and can also perform fingerprint recognition in the image display area, wherein the fingerprint refers to a pattern generated by unevenness on a front surface of a human finger 50. The above-mentioned array substrate 10 can display image on the side opposite from the fingerprint recognition device 30, that is, the surface of the array substrate 10 opposite from the fingerprint recognition device 30 can be defined as a display surface, and the surface opposite of the display surface (i.e., the surface of the array substrate 10 facing the fingerprint recognition device 30) may be defined as a back surface. It should be noted that the display surface and the back surface may both be flat.

The fingerprint recognition device 30 identifies fingerprint information. In one embodiment, the fingerprint recognition device 30 may be disposed on the back surface of the array substrate 10. The surface of the fingerprint recognition device 30 facing the back surface is a concave-convex surface. The concave-convex surface may include a concave surface and a convex surface. Each of the concave surface and the convex surface may be a regularly or irregularly curved surface or a flat surface. There is a gap between the convex surface 3021 of the concave-convex surface of the fingerprint recognition device 30 and the back surface of the array substrate 10. That is, the gap between the convex surface 3021 of the concave-convex surface and the back surface of the array substrate 10 is non-zero. It is understandable that the convex surface 3021 of the concave-convex surface may be a receiving surface of the fingerprint recognition device 30 for receiving fingerprint information.

The connection portion 20 is for connecting the fingerprint recognition device 30 to the back surface of the array substrate 10. In one embodiment, the connection portion 20 can include a first surface 201 and a second surface opposite to the first surface 201.

The first surface 201 can be connected to the concave surface 3011 of the concave-convex surface of the fingerprint recognition device 30, and the second surface can be connected to the back surface of the array substrate 10. It should be noted that the first surface 201 and the second surface may both be flat or curved.

It can be seen from above that in the embodiment, the surface of the fingerprint recognition device 30 facing the back surface of the array substrate 10 is a concave-convex surface, that is, the fingerprint recognition device 30 is a non-flat structure. After the concave surface 3011 is connected to the first surface 201 (i.e., the surface of the connecting portion 20 opposite from the array substrate 10) of the connection portion 20, the convex surface 3021 of the concave-convex surface protrudes in the direction towards the array substrate 10 over the concave surface. Therefore the thickness of the connection portion 20 can be increased to reduce the occurrence of wrinkles and indentations between the connection portion 20 and the fingerprint recognition device 30 and between the connection portion 20 and the display panel, while the gap between the fingerprint recognition device 30 and the array substrate 10 is not increased. Thereby, the gap between the fingerprint recognition device 30 and the array substrate can be within a set value, thereby ensuring fingerprint imaging effect and improving fingerprint recognition sensitivity.

In addition, the distance between the convex surface 3021 of the concave-convex surface and the back surface of the array substrate 10 is non-zero, which not only improves fingerprint imaging effect, but also facilitates thinning of the array substrate 10, thereby reducing production cost of the array substrate 10.

It should be understood that although the distance between the convex surface 3021 of the concave-convex surface in the fingerprint recognition device 30 and the back surface of the array substrate 10 is non-zero, the distance between the two cannot be infinitely large because too long distance will affect the fingerprint imaging effect. Therefore, in order to further improve fingerprint imaging effect, it is necessary to control the distance H between the convex surface of the concave-convex surface in the fingerprint recognition device 30 and the back surface of the array substrate 10 within a set value, which may be 50 μm. That is, the gap distance between the convex surface 3021 of the concave-convex surface in the fingerprint recognition device 30 and the back surface of the array substrate 10 can be designed to be less than or equal to about 50 μm.

It should be noted that the above mentioned gap distance is a shortest, vertical distance between the convex surface 3021 of the concave-convex surface in the fingerprint recognition device 30 and the back surface of the array substrate 10.

A specific embodiment of present disclosure is described below with reference to the accompanying drawings.

In one embodiment of present disclosure, the array substrate 10 can be an organic light emitting array substrate, that is, the display panel can be an OLED (Organic Light-Emitting Diode) display panel. The organic light emitting array substrate can serve as a light source to provide reflected light required for fingerprint imaging. That is, light emitted from the organic light emitting array substrate is projected onto the finger 50 on the display side of the display panel, and is reflected by the finger 50 on to the fingerprint recognition device 30, as indicated by a dotted arrow in FIG. 2A. The fingerprint recognition device 30 can recognize the reflected light containing the fingerprint information.

It should be noted that the array substrate 10 is not limited to the organic light emitting array substrate. It may be a liquid crystal display array substrate or other array substrate for display. In one embodiment of present disclosure, the array substrate 10 is an organic light emitting array substrate, as shown in FIG. 2A. The array substrate 10 may include an organic light emitting layer 101 and a light shielding layer 102 disposed between the organic light emitting layer 101 and the fingerprint recognition device 30. The light shielding layer 102 can include a small aperture imaging area that is opposite the convex surface 3021 of the concave-convex surface in the fingerprint recognition device 30. The light reflected by the fingerprint can be projected through the small aperture imaging area to the convex surface 3021 of the concave-convex surface of the fingerprint recognition device 30, thereby realizing the functions of fingerprint collection and recognition. As shown in FIG. 2C, the array substrate 10 comprises a light shielding layer 102, and the light shielding layer 102 comprises a small aperture imaging area having a plurality of openings 1021, and an orthographic projection of the small aperture imaging area on the mounting substrate overlaps an orthographic project of the convex surface of the fingerprint recognition device on the mounting substrate.

In one embodiment of present disclosure, the organic light-emitting layer 101 may include a plurality of light-emitting devices at intervals. An orthographic projection of the small aperture imaging area on the organic light-emitting layer 101 is disposed at an interval between the light-emitting devices to reduce the effect of the light emission of the light-emitting device on the imaging of the aperture imaging area. It should be noted that the array substrate 10 may further include other light shielding components such as signal traces. In order to prevent the other light shielding components from affecting the imaging effect, the small aperture imaging area and the other light shielding components may be disposed at different locations.

As shown in FIG. 2A, the small aperture imaging area may include a plurality of openings 1021, and each of the openings 1021 may be used for passing partial fingerprint reflected light. That is, each opening 1021 images a partial fingerprint based on a small hole imaging principle. The light reflected from a partial fingerprint passes through the opening and projects an inverted image of the partial fingerprint on the convex surface of the fingerprint recognition device. After the fingerprint recognition device 30 obtains the partial fingerprint image by each opening 1021, through image extraction and processing, the partial fingerprint images can be spliced and integrated to form a complete and clear fingerprint image. In order to facilitate the splicing of each part of the fingerprint image, the partial fingerprint images by two adjacent apertures 1021 can contain a shared portion of the fingerprint image.

In addition, the plurality of openings 1021 in the small aperture imaging area may be arranged in an array. In this way, the openings 1021 may be evenly arranged in the row direction and the column direction to ensure a certain transmittance of the reflected light of the fingerprint, thereby improving fingerprint imaging effect and fingerprint recognition sensitivity.

In one embodiment of present disclosure, as shown in FIGS. 2A and 3, the concave surface 3011 of the concave-convex surface of the fingerprint recognition device 30 surrounds the convex surface 3021. Since the concave surface 3011 is used for connection with the connection portion 20 to mount the fingerprint recognition device 30 onto the back surface of the substrate 10, the connection portion 20 can be disposed as a ring structure to surround the convex surface 3021 of the concave-convex surface of the fingerprint recognition device 30. As such, the connection area between the connection portion 20 and the fingerprint recognition device 30 can be increased. Accordingly, the connection stability of the fingerprint recognition device 30 can be improved. Furthermore, the reflected light by the fingerprint can be prevented from leaking, thereby improving fingerprint recognition sensitivity.

In one embodiment of present disclosure, as shown in FIG. 2B, the connection portion can be a frame sealant. That is, the stable bonding between the array substrate 10 and the fingerprint recognition device 30 can be achieved through the connection portion 20. In this embodiment, by using the frame sealant as the connecting portion 20, not only the difficulty of connecting the array substrate 10 and the fingerprint recognition device 30 is reduced, but also the connection portion 20 has a certain buffering performance.

Optionally, the frame sealant may be made of a flowing rubber or a hard rubber. The hard rubber may be, for example, a foam rubber or a polyethylene terephthalate (PET) double-sided tape. The advantages of foam rubber include elasticity, light weight and reliable performance. The foam-based foam rubber has excellent sealing properties, compression resistance, flame resistance and wettability. The PET double-sided tape has the advantages of good mechanical properties, high temperature resistance, low temperature resistance, low gas and water vapor permeability. Therefore, the frame sealant made of the foam rubber or the PET double-sided tape can improve the sealing performance, the shielding performance and the cushioning performance of the fingerprint recognition device 30.

In one embodiment of present disclosure, as shown in FIG. 2A, the area of the concave surface 3011 of the concave-convex surface of the fingerprint recognition device 30 may be smaller than the area of the first surface 201 of the connection portion 20. That is, an orthographic projection the concave surface 3011 on the first surface 201 of the connection portion 20 is within the first surface 201. In this way, the connection stability of the fingerprint recognition device 30 and the connection portion 20 is ensured. Furthermore an edge sealant 40 can be prevented from dropping onto the array substrate 10 during the following edge sealing step, thereby improving the quality of the products.

Optionally, as shown in FIGS. 2A and 2B, an edge sealant 40 can be applied at the corner of the fingerprint recognition device 30 and the first surface 201 of the connection portion 20. As such, the connection stability between the fingerprint recognition device 30 and the connection portion 20 can be improved. Furthermore, the connection between the connection portion 20 and the fingerprint recognition device 30 can be sealed to prevent the leakage of the reflected light of the fingerprint, thereby improving the sensitivity of fingerprint recognition.

In one embodiment, the edge sealant may be in a liquid state before a corner is formed by the fingerprint recognition device 30 and the first face 201 of the connection portion 20. That is, after the first surface 201 of the connection portion 20 is connected with the fingerprint recognition device 30, a liquid glue can be dropped to the corner formed by the fingerprint recognition device 30 and the first surface 201 of the connection portion 20. Then, the liquid glue is solidified to form the edge sealant 40, which is packaged at the corner formed by the fingerprint recognition device 30 and the first face 201 of the connecting portion 20.

It should be noted that the material of edge sealant 40 may be the same as the material of the frame sealant, but not limited thereto. The material of the edge sealant 40 may also be different from the material of the frame sealant, depending on the specific conditions.

In some embodiments, the fingerprint recognition device 30 may be disposed on the whole back surface of the array substrate 10 or may be disposed only below the small aperture imaging area, which is not limited herein.

In one embodiment of present disclosure, as shown in FIGS. 2A and 3, the fingerprint recognition device 30 may include a mounting substrate 301 and a fingerprint recognition unit 302. The surface of the mounting substrate 301 facing the back surface of the array substrate 10 may include a fingerprint recognition area and a non-recognition area, wherein the non-recognition area is the concave surface 3011 of the above mentioned concave-convex surface. The fingerprint recognition unit 302 is disposed in the fingerprint recognition area, wherein the surface of the fingerprint recognition unit 302 facing the back surface of the array substrate 10 is the above mentioned convex surface 3021 of the concave-convex surface 3021.

FIG. 2B shows a schematic top view of a display panel according to one embodiment of the present disclosure. In one embodiment, as shown in FIG. 2B, the connection portion 20 is an square annular structure, and the connection portion surrounds the fingerprint recognition unit. The edge sealant 40 may be in a form of a square annular structure formed at the corner formed by the fingerprint recognition device 30 and the first face of the connecting portion 20.

In one embodiment, the fingerprint recognition unit 302 can be an image sensor. The mounting substrate 301 is not only used to connect the fingerprint recognition device 30 with the connection portion 20, but the mounting substrate 301 can also be a driving circuit board of the fingerprint recognition unit 302. The fingerprint recognition unit 302 and the driving circuit board are in direct contact, which reduces the length of the connecting leads between the fingerprint recognition unit 302 and the driving circuit board, thereby reducing the interference on the connecting leads during transmission.

It should be noted that the display panel may further include a glass cover 60 disposed on a side of the array substrate 10 opposite from the fingerprint recognition device 30.

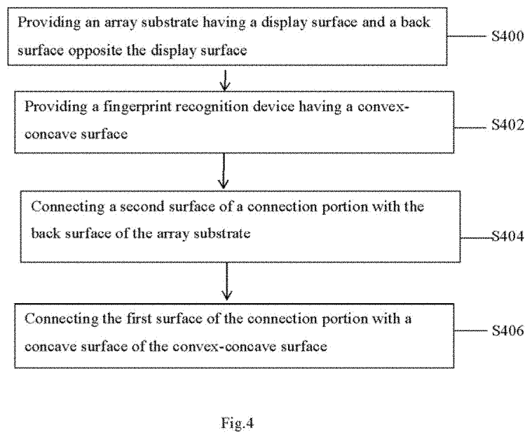

Further, some embodiments of the present disclosure further provide a method for manufacturing a display panel. Referring to FIG. 4, the method of manufacturing the display panel may include the following steps S400-S406:

Step S400 includes providing an array substrate 10, wherein the array substrate 10 includes a display surface and a back surface opposite to the display surface.

Step S402 includes providing a fingerprint recognition device 30, wherein one surface of the fingerprint recognition device 30 is a concave-convex surface.

Step S404 includes connecting the second surface of the connection portion 20 with the back surface of the array substrate.

Step S406 includes connecting the first surface 201 of the connection portion, which is opposite from the second surface of the connection portion, to the concave surface 3011 of the concave-convex surface, such that a gap is formed between the convex surface 3021 of the concave-convex surface and the back surface.

In one embodiment, the surface of the fingerprint recognition device 30 facing the back surface of the array substrate 10 is a concave-convex surface, that is, the fingerprint recognition device 30 is a non-flat structure. After the concave surface 3011 is connected to the first surface 201 (i.e., the surface of the connection portion 20 opposite from the array substrate 10) of the connection portion 20, the convex surface 3021 of the concave-convex surface protrudes in the direction towards the array substrate 10 over the concave surface. Therefore the thickness of the connection portion 20 can be increased to reduce the occurrence of wrinkles and indentations between the connection portion 20 and the fingerprint recognition device 30 and between the connection portion 20 and the display panel while the gap distance between the fingerprint recognition device 30 and the array substrate 10 is avoided being increased. As such, the gap distance between the identification device 30 and the array substrate 10 can be within a set value, which in turn ensures fingerprint imaging effect and improves fingerprint recognition sensitivity.

In addition, the distance between the convex surface 3021 of the concave-convex surface and the back surface of the array substrate 10 is non-zero, which not only improves the fingerprint imaging effect, but also facilitates thinning of the array substrate 10, thereby reducing the production cost of array substrate 10.

It should be noted that, in the process of manufacturing the display panel, the order of step S400, step S402, step S404, and step S406 is not limited to the above description, that is, the order of step S400, step S402, step S404, and step S406 may not be in the same way, as long as the above mentioned display panel can be manufactured.

In one embodiment, in actual manufacturing process of a display panel, a distance from the convex surface 3021 to the concave surface 3011 of the concave-convex surface of the fingerprint recognition device 30 may be measured first. Then, a connection portion 20 having a larger thickness than the distance from the convex surface 3021 to the concave surface 3011 of the concave-convex surface of the fingerprint recognition device may be selected. That is, the distance from the first surface 201 to the second surface of the connection portion 20 in the embodiment is greater than the distance from the convex surface 3021 to the concave surface of the concave-convex surface. Herein the distance refers to the shortest distance between the two surfaces. In this method, the first surface 201 of the connection portion 20 is connected to the back surface of the array substrate 10, and the second surface of the connection portion 20 is connected to the concave surface 3011 of the fingerprint recognition device 30. As such, a gap can be formed between the convex surface 3021 of the concave-convex surface in the fingerprint recognition device 30 and the back surface of the array substrate 10.

In addition, some embodiments of the present disclosure also provide a display apparatus including the display panel described in any of the foregoing embodiments.

In some embodiments, the display panel can be an OLED display panel or a liquid crystal display panel. The display apparatus can be a terminal apparatus such as a mobile phone or a tablet computer.

Other embodiments of the present disclosure will be obvious to those skilled in the art. The present disclosure is intended to cover any variations, uses, or adaptations of the disclosure, which are in accordance with the general principles of the application and include common general knowledge or common technical means in the art that are not disclosed herein. The specification and embodiments are to be considered as illustrative only.

The above is only an exemplary embodiment of the present disclosure, and is not intended to limit the scope of the present disclosure. The scope of the present disclosure is defined by the appended claims.

1. A display panel, comprising:
an array substrate having a display surface and a back surface opposite the display surface;
a fingerprint recognition device on a side of the back surface of the array substrate; and
a connection portion between the array substrate and the fingerprint recognition device, the connection portion having a first surface and a second surface opposite the first surface,
wherein a surface of the fingerprint recognition device facing the back surface of the array substrate is a convex-concave surface comprising a concave surface and a convex surface, and there is a gap between the convex surface and the back surface.

2. The display panel according to claim 1, wherein the fingerprint recognition device comprises:
a mounting substrate; and
a fingerprint recognition unit,
wherein a surface of the mounting substrate facing the back surface of the array substrate comprises a fingerprint recognition area and a non-recognition area, the non-recognition area is the concave surface of the concave-convex surface, the fingerprint recognition unit is on the fingerprint recognition area, and a surface of the fingerprint recognition unit facing the back surface of the array substrate is the convex surface of the concave-convex surface.

3. The display panel according to claim 2, wherein the array substrate comprises a light shielding layer, the light shielding layer comprises a small aperture imaging area, and an orthographic projection of the small aperture imaging area on the mounting substrate overlaps an orthographic project of the convex surface of the fingerprint recognition device on the mounting substrate.

4. The array substrate according to claim 3, wherein the small aperture imaging area comprises a plurality of openings in an array.

5. The display panel according to claim 1, wherein
the first surface of the connection portion connects the concave surface of the concave-convex surface of the fingerprint recognition device, and the second surface of the connection portion connects the back surface of the array substrate.

6. The display panel according to claim 1, wherein a gap distance of the gap between the convex surface and the back surface is less than or equal to about 50 μm.

7. The display panel according to claim 1, wherein an orthographic projection of the concave surface on the first surface is within the first surface.

8. The display panel according to claim 1, wherein a shortest distance between the first surface and the second surface of the connection portion is greater than a shortest distance from the convex surface to the concave surface of the concave-convex surface.

9. The display panel according to claim 1, wherein the connection portion is an annular structure, and the connection portion surrounds the convex surface.

10. The display panel according to claim 1, wherein the connection portion comprises a frame sealant.

11. The display panel according to claim 1, wherein a corner formed by the fingerprint recognition device and the first surface is sealed with an edge sealant.

12. The display panel according to claim 1, wherein the array substrate is an organic light emitting array substrate.

13. The array substrate according to claim 12, wherein the organic light emitting array substrate comprises an organic light emitting layer, and the light shielding layer is between the organic light emitting layer and the fingerprint recognition device.

14. The array substrate according to claim 13, wherein the organic light emitting layer comprises a plurality of light-emitting devices at intervals, and an orthographic projection of the small aperture imaging area on the organic light emitting layer is at the intervals among the light-emitting devices.

15. The array substrate according to claim 2, wherein the mounting substrate comprises a driving circuit board configured to drive the fingerprint recognition unit.

16. A method for manufacturing a display panel, comprising:
providing an array substrate having a display surface and a back surface opposite the display surface;
providing a fingerprint recognition device; and
connecting the array substrate and the fingerprint recognition device through a connection portion having a first surface and a second surface opposite the first surface,
wherein a surface of the fingerprint recognition device facing the back surface is a convex-concave surface comprising a concave surface and a convex surface, and there is a gap between the convex surface and the back surface.

17. The method according to claim 16, wherein the first surface of the connection portion is configured to be connected to the concave surface of the concave-convex surface of the fingerprint recognition device, and the second surface of the connection portion is configured to be connected to the back surface of the array substrate.

18. The manufacturing method according to claim 17, wherein a shortest distance between the first surface and the second surface of the connection portion is greater than a shortest distance from the convex surface to the concave surface of the concave-convex surface, thereby forming the gap between the convex surface and the back surface.

19. A display apparatus comprising the display panel according to claim 1.
